(19) United States
(12) Patent Application Publication
(10) Pub. No.: US 2008/0211023 A1
(43) Pub. Date: Sep. 4, 2008

(54) SEMICONDUCTOR MEMORY DEVICE AND MANUFACTURING METHOD OF SEMICONDUCTOR MEMORY DEVICE

(75) Inventor: Tomoaki SHINO, Kawasaki-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/015,171

(22) Filed: Jan. 16, 2008

(30) Foreign Application Priority Data
Jan. 17, 2007 (JP) 2007-008022

(51) Int. Cl. H01L 29/786; H01L 21/336

(52) U.S. Cl. 257/347; 438/157; 257/E29.273; 257/E21.411

(57) ABSTRACT

A semiconductor memory device has a first semiconductor layer and a second semiconductor layer facing each other across a back gate insulation film, a first conductive type plate provided in the first semiconductor layer, a gate insulation film provided on a surface of the second semiconductor layer so as to be in contact with a second surface opposite to a first surface in contact with the back gate insulation film, a gate electrode provided so as to be in contact with the gate insulation film, a first conductive type body region provided in the region facing the gate electrode across the gate insulation film in the second semiconductor layer, a second conductive type source layer and a second conductive type drain layer provided to sandwich the body region in the second semiconductor layer and a second conductive type diffusion layer provided in a surface region of the first semiconductor layer facing the source layer and the drain layer across the back gate insulation film, wherein the body region is in an electrically floating state and stores data by accumulating or discharging charges.

### CROSS-REFERENCE TO RELATED APPLICATION

This application is based upon and claims the benefit of priority from the prior Japanese Patent Application No. 2007-8022, filed on 17, Jan., 2007; the entire contents of which are incorporated herein by reference.

### BACKGROUND OF THE INVENTION

The present invention relates to a semiconductor memory device and a manufacturing method of the semiconductor memory device, and more particularly, to a Floating Body Cell (hereinafter, referred to as an FBC) memory device having a memory cell for storing data depending on the amount of holes accumulated in a body region and a manufacturing method of the FBC memory device.

An FBC memory device is excellent in miniaturization as compared with a 1T-1C (1 Transistor-1 Capacitor) type DRAM. Accordingly, the FBC memory device has been broadly used as a semiconductor memory device in place of a 1T-1C type DRAM.

A memory cell of the FBC memory device is ordinarily composed of a MISFET formed on an SOI substrate. In the FBC memory device, a source layer, a drain layer and a body region are formed on an SOI layer. The body region sandwiched between the source layer and the drain layer is in an electrically floating state. For example, when the FBC memory device is composed of an N-type FET, the memory cell can store data depending on the amount of holes accumulated in the body region.

When the difference ΔVth between the threshold voltage of a memory cell storing data “0” (hereinafter, referred to as “0” cell) and the threshold voltage of a memory cell storing data “1” (hereinafter, referred to as “1” cell) is small, the number of defective bits is increased because it is difficult to identify the data “0” and the data “1”. A reason why the difference ΔVth becomes small is that a surface of a support substrate is inverted and thus the capacitance Csub between the body region and the support substrate is reduced.

Further, when a back gate insulation film is thinned to secure the capacitance Csub between the body region and the support substrate, a leak current between the body region, the source layer and the drain layer is increased and thus the data retention time is reduced when the voltage of the support substrate is set to a negative voltage (Japanese Patent Application Laid-Open No. 2003-31693).

### SUMMARY OF THE INVENTION

According to a first aspect of the invention, there is provided a semiconductor memory device, comprising:

a first semiconductor layer and a second semiconductor layer facing each other across a back gate insulation film;

a first conductive type plate provided in the first semiconductor layer;

a gate insulation film provided on a surface of the second semiconductor layer so as to be in contact with a second surface opposite to a first surface in contact with the back gate insulation film;

a gate electrode provided so as to be in contact with the gate insulation film;

a first conductive type body region provided in the region facing the gate electrode across the gate insulation film in the second semiconductor layer;

a second conductive type source layer and a second conductive type drain layer provided to sandwich the body region in the second semiconductor layer; and

a second conductive type diffusion layer provided in a surface region of the first semiconductor layer facing the source layer and the drain layer across the back gate insulation film,

wherein the body region is in an electrically floating state and stores data by accumulating or discharging charges.

According to a second aspect of the invention, there is provided a method of manufacturing a semiconductor memory device for storing data by accumulating or discharging charges in a body region in an electrically floating state, comprising:

forming a structure which has a first semiconductor layer, a second semiconductor layer, a gate insulation film, and a gate electrode, the first semiconductor layer including a first conductive type plate and facing the second semiconductor layer across a back gate insulation film, the second semiconductor layer including a first conductive type body region;

forming a second conductive type diffusion layer in the plate by introducing second conductive type impurities into the first semiconductor layer using the gate electrode as a mask; and

forming a source layer and a drain layer by introducing second conductive type impurities into the second semiconductor layer using the gate electrode as a mask.

### BRIEF DESCRIPTION OF THE DRAWINGS

FIG. 1 is a plan view of an FBC memory device of the first embodiment of the present invention.

FIG. 2 is a sectional view taken along a line 2-2 of FIG. 1.

FIG. 3 is a sectional view of the source layer S along a line 3-3 of FIG. 1.

FIG. 4 is a sectional view of the gate electrode G and the body region B along a line 4-4 of FIG. 1.

FIG. 5 is a sectional view of the memory cell region and a logic circuit region of the FBC memory device of the first embodiment.

FIG. 6 is a graph showing a result of simulation of the relation between a threshold voltage and a plate voltage in a data read-out operation.

FIG. 7 shows input waveforms used in the simulation of FIG. 6.

FIGS. 8 (A) and (B) are graphs showing a potential distribution (equivalent potential contour line).

FIG. 9 is a graph showing the maximum electric field in the silicon layer 10 in the memory cell as a function of the plate voltage when the data “0” is held.

FIG. 10 is a sectional view of a memory cell of an FBC memory device.

FIG. 11 is a graph showing how the impurity concentration is distributed in the body region B and the plate PL.

FIG. 12 is a sectional view showing the method of manufacturing the FBC memory device of the first and second embodiments of the present invention.

FIG. 13 is a sectional view subsequent to FIG. 12.

FIG. 14 is a sectional view subsequent to FIG. 13.

FIG. 15 is a sectional view subsequent to FIG. 14.

FIG. 16 is a sectional view of an FBC memory device of the third embodiment of the present invention.

FIG. 17 is a sectional view of the source layer S of the FBC memory device of the third embodiment of the present invention.

FIG. 18 is a sectional view of an FBC memory device of the fourth embodiment of the present invention.

FIG. 19 is a sectional view of the source layer S of the FBC memory device of the fourth embodiment of the present invention.

FIG. 20 is a sectional view of a gate electrode G and a body region B of the FBC memory device of the fourth embodiment of the present invention.

FIG. 21 is a sectional view showing the method of manufacturing the FBC memory device of the fourth embodiment of the present invention.

FIG. 22 is a plan view of an FBC memory of the fifth embodiment of the present invention.

FIG. 23 is a sectional view of a gate electrode G and the body region B along a line 23-23 of FIG. 22.

FIG. 24 is a sectional view of a source layer S along a line 24-24 of FIG. 22.

FIG. 25 is a sectional view showing the method of manufacturing the FBC memory device of the fifth embodiment of the present invention.

FIG. 26 is a sectional view subsequent to FIG. 25.

FIGS. 27 and 28 are sectional views when the N-type diffusion layer 11 is formed.

### DETAILED DESCRIPTION OF THE INVENTION

Embodiments according to the present invention will be explained below with reference to the drawings. The embodiments do not restrict the scope of the present invention.

### First Embodiment

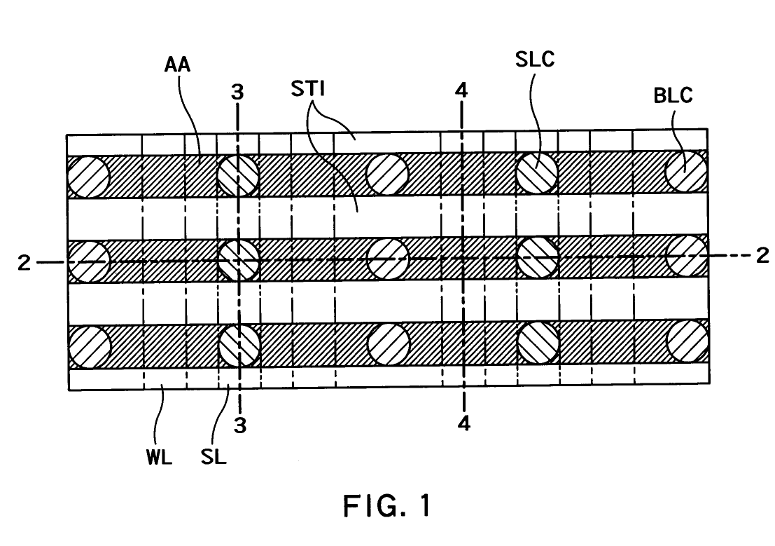

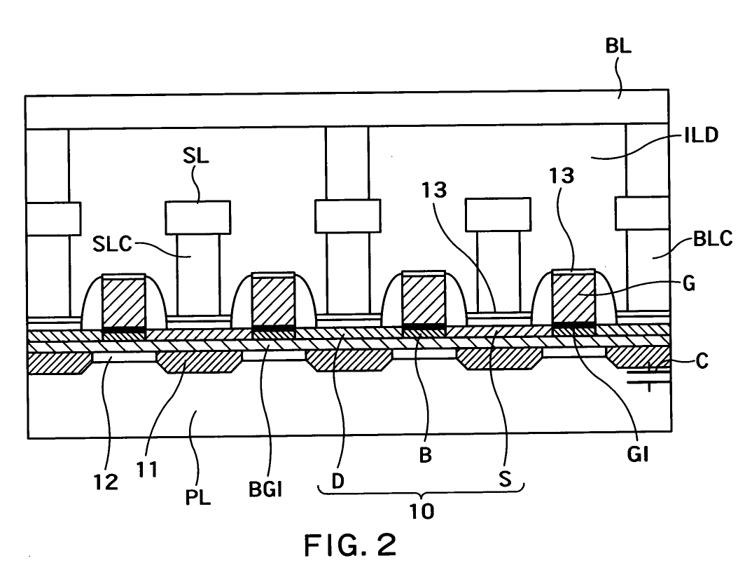

First, a first embodiment of the present invention will be explained. FIG. 1 is a plan view of a Floating Body Cell (hereinafter, referred to as an FBC) memory device of the first embodiment of the present invention. In a memory cell region, a bit line BL and a word line WL of FIG. 2 (gate electrode G of FIG. 2) intersects with each other. The memory cell is provided corresponding to the intersecting point of the bit line BL and the word line WL. A source line SL extends in parallel with the word line WL. An active region AA extends in a stripe manner substantially in parallel with the bit line BL thereabove. An STI (Shallow Trench Isolation) is provided between the active region AA. In a logic region, a MISFET which has a source layer S, a drain layer D and the gate electrode G of FIG. 2, is formed in the active region M.

FIG. 2 is a sectional view taken along a line 2-2 of FIG. 1. As shown in FIG. 2, the FBC memory device of the first embodiment of the present invention is provided with a silicon layer 10, a plate PL, a back gate insulation film BGI, the bit line BL, the source line SL, a bit line contact BLC and an inter layer dielectric ILD. The drain layer D, the source layer S and a body region B are formed on the silicon layer 10. A gate insulation film GI, the gate electrode G (word line WL of FIG. 1) and a silicide layer 13 are formed on the silicon layer 10. An N-type (second conductive type) diffusion layer 11 and a P-type (first conductive type) diffusion layer 12 are formed in a surface part of the plate PL.

The plate PL, which is made of a semiconductor material, is, for example, a bulk silicon substrate. Boron having a concentration of 1×10¹⁸ cm⁻³ is introduced into the plate PL. The back gate insulation film BGI is provided on the plate PL. The back gate insulation film BGI is a silicon oxide having a thickness of, for example, 8 nm. The N-type diffusion layer 11 is provided in a surface of the plate PL which faces the source layer S and the drain layer D across the back gate insulation film BGI. The P-type diffusion layer 12 is provided in a surface of the plate PL which faces the body region B across the back gate insulation film BGI.

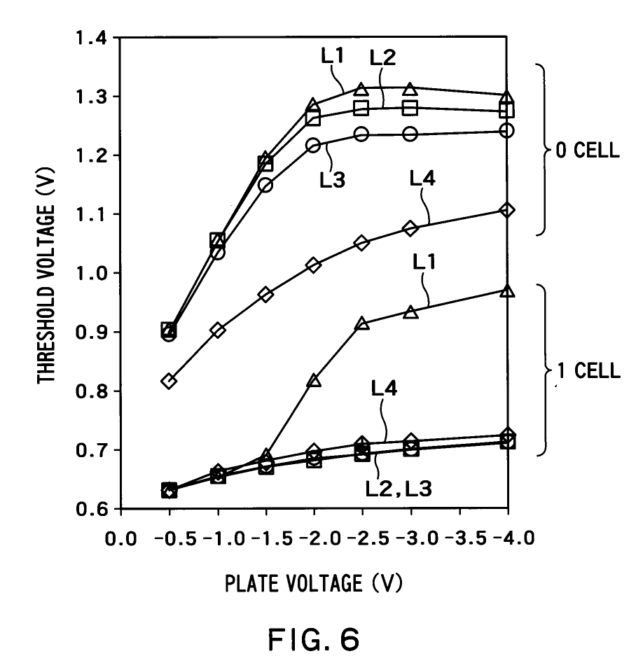

The N-type impurity concentration in the N-type diffusion layer 11 is, for example, 2×10¹⁸ cm⁻³. With this arrangement, since a gated diode structure is formed to the plate PL, it is possible to make the difference ΔVth of the threshold voltages between the data “0” and the data “1” of the FBC memory device of the first embodiment of the present invention (L2 to L4 of FIG. 6) larger than a conventional FBC memory device (L1 of FIG. 6) as shown in FIG. 6. FIG. 6 will be described later.

The source layer S, the drain layer D and the body region B are provided on the back gate insulation film BGI. With this arrangement, the source layer S, the drain layer D and the body region B are electrically Insulated from the plate PL. The body region B is interposed between the drain layer D and the source layer S and in an electrically floating state. The body region B can accumulate charges to store data. The source layer S and the drain layer D contain N-type impurities of, for example, about 10²⁰ cm⁻³.

The gate insulation film GI is made of, for example, a silicon oxide, a silicon nitride, a stacked layer thereof or the like and provided on the body region B. The gate electrode G has, for example, polysilicon and provided on the gate insulation film GI. The silicide layer 13 is provided on the surface of each of the source layer S, the drain layer D and the gate electrode G.

The bit line BL is connected to the drain layer D of the memory cell through the bit line contact BLC. The source line SL is connected to the source layer S of the memory cell through the source line contact SLC. The gate electrode G also acts as the word line WL of FIG. 1.

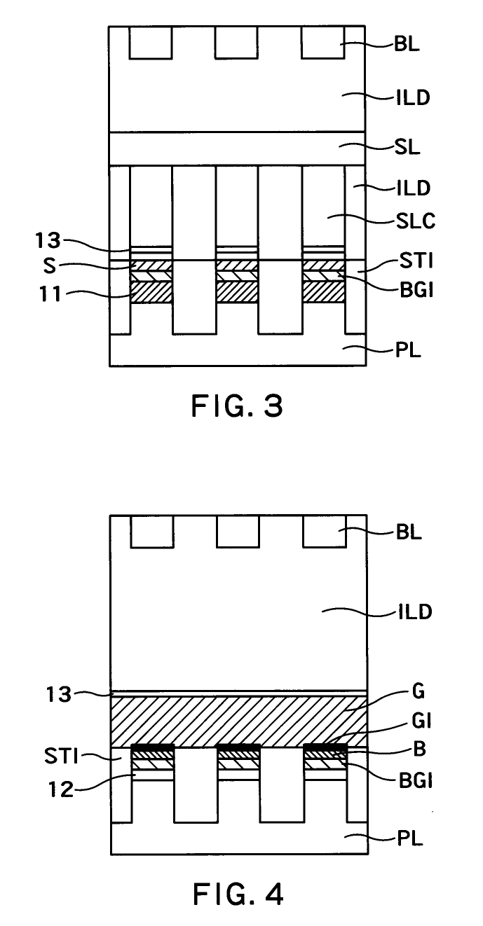

FIG. 3 is a sectional view of the portion of the source layer S along a line 3-3 of FIG. 1. FIG. 4 is a sectional view of the portions of the gate electrode G and the body region B along a line 4-4 of FIG. 1. As shown in FIG. 3, the N-type diffusion layer 11 is located in a surface region of the support substrate under the source layer S and the drain layer D, and it faces the source layer S and the drain layer D across the back gate insulation film BGI. As shown in FIG. 4, the back gate insulation film BGI is located under the body region B, and the gate insulation film GI is located on the body region B. Further, as shown in FIG. 2, the body region B is provided such that the front, back, right and left portions thereof are surrounded by the source layer S, the drain layer D and the STI. With this arrangement, the body region B is in an electrically floating state. In the memory cell region, the drain layer D, the source layer S, the body region B, the gate insulation film GI and the gate electrode G constitute the memory cell, and memory cells having the same structure are provided in a matrix-shaped.

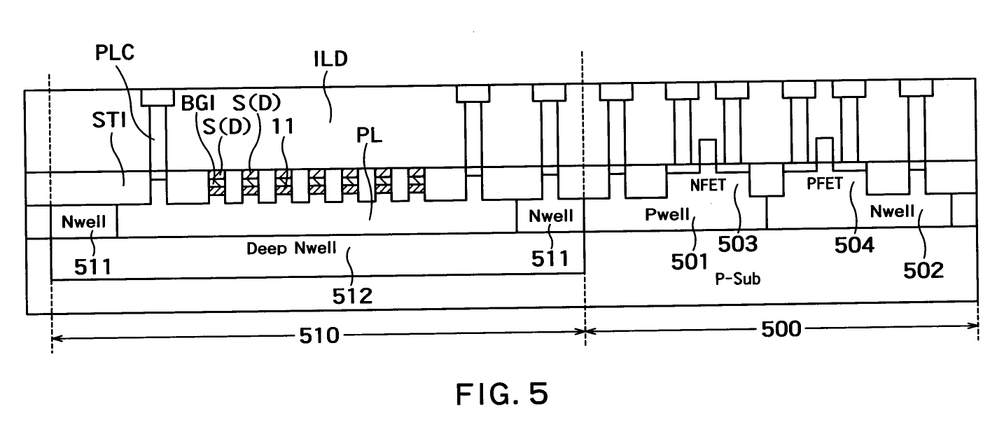

FIG. 5 is sectional view of the memory cell region and a logic circuit region of the FBC memory device of the first embodiment. In the logic circuit region 500, a P-type well (Pwell) 501 and an N-type well (Nwell) 502 are formed on a substrate P-Sub. An N channel transistor (NFET) 503 is formed to the P-type well 501, and a P channel transistor (PFET) 504 is formed to the N-type well 502.

In a memory cell region 510, the plate PL is formed on the substrate P-Sub up to the same depth as the P-type well 501 of the logic circuit region 500. A plate line contact PLC is formed to an edge of the memory cell region 510, and a voltage (plate voltage) is applied to the plate PL. The N-type diffusion layer 11 is in an electrically floating state. A ring-shaped N-type well (Nwell) 511 is formed around the plate PL. An N-type well (Deep Nwell) 512 is also formed to the bottom of the plate PL. A voltage is applied to the ring-shaped N-type well 511.

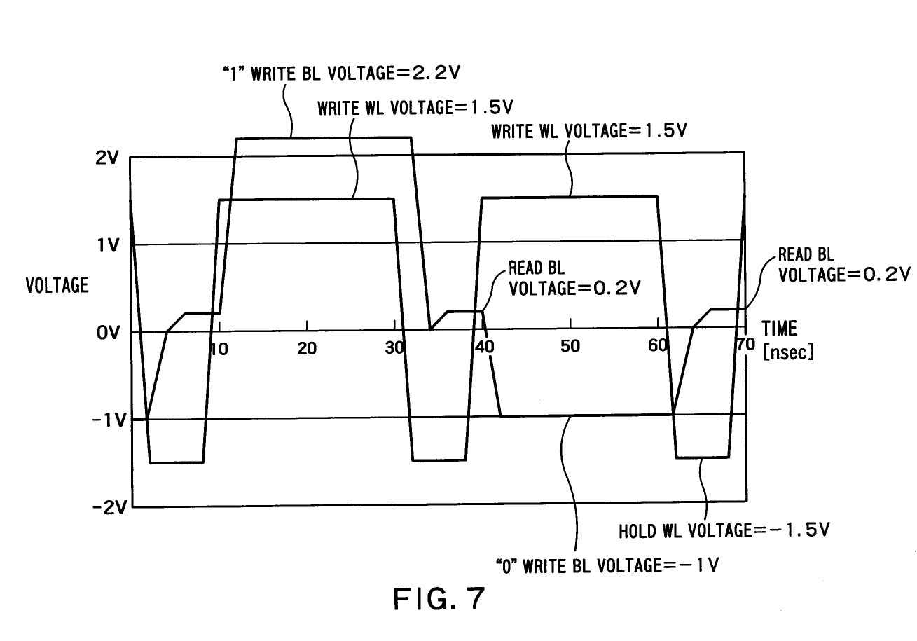

FIG. 6 is a graph showing a result of simulation of the relation between a threshold voltage and a plate voltage in a data read-out operation. In the structure used in the simulation, the SOI layer has a film thickness of 15 nm, the back gate insulation film BGI has a film thickness of 8 nm, the gate insulation film GI has a film thickness of 6 nm, a gate length is 0.12 μm, the P-type impurity concentration of the body region B is 5×10¹⁷ cm⁻³, and the P-type impurity concentration of the plate PL is 8.3×10¹⁷ cm⁻³. FIG. 7 shows input waveforms used in the simulation of FIG. 6.

As shown by a line L1 of FIG. 6, as the plate voltage is reduced, the threshold voltage of the “1” cell is increased and approaches to the threshold voltage of the “0” cell in the conventional FBC memory device. This is because that when the plate voltage is lower than −1.5 V, the surface of the plate PL is in an inversion state, and the capacitance Csub between the body region B and the plate PL is reduced. As a result, when the plate voltage is −1.5 V, the difference ΔVth is 0.501 V at the maximum.

A line L2 of FIG. 6 shows a result of simulation of a structure having the N-type diffusion layer 11 under the source layer S and the drain layer D of the FBC memory device of the first embodiment of the present invention (refer to FIG. 2). In the FBC memory device of the first embodiment of the present invention, even if the plate voltage is reduced, the threshold voltage of the “1” cell is not increased. As a result, when the plate voltage is −2.5 V, the difference ΔVth was 0.589 V at the maximum.

A reason why the difference ΔVth between the threshold voltages of the FBC memory device of the first embodiment of the present invention is larger than that of the conventional FBC memory device is as described below. In the FBC memory device of the first embodiment of the present invention, the gated diode structure is formed on the surface of the plate PL as explained referring to FIG. 2. The gated diode structure is a structure having a PN junction which has a P-type semiconductor and an N-type diffusion layer formed on a surface thereof and further has a gate insulation film and a gate electrode formed on the N-type the diffusion layer. In the gated diode structure, when the surface of the plate PL is Inverted, electrons are supplied from the N-type diffusion layer 11 to the inversion layer. Accordingly, the width of a depletion layer formed on the surface of the plate PL just under the body region B is reduced, and the capacitance Csub between the body region B and the plate PL is increased. As a result, it is possible to suppress an increase of the threshold voltage of the “1” cell caused by the reduction of the plate voltage as compared with the conventional FBC memory device.

The lines L2 to L4 exhibit the change of the threshold voltage which depends on the dose of N-type impurities in an ion implantation process for forming the N-type diffusion layer 11. The line L2 shows a case in which the dose of the N-type impurities is 2×10¹³ cm⁻². The peak of the N-type impurity concentration of the N-type diffusion layer 11 is about 2×10¹⁸ cm⁻³. The line L3 shows a case in which the dose of the N-type impurities is 1.8×10¹⁴ cm⁻². The peak of the N-type impurity concentration of the N-type diffusion layer 11 is about 2×10¹⁹ cm⁻³. The line L4 shows a case in which the dose of the N-type impurities is 5×10¹⁴ cm⁻². The peak of the N-type impurity concentration of the N-type diffusion layer 11 is about 5×10¹⁹ cm⁻³.

As shown in FIG. 6, the threshold voltage of the “0” cell is reduced by an increase of the dose of N-type impurities, that is, by an increase of N-type impurity concentration. Accordingly, the difference ΔVth between the “0” cell and 1” cell is also reduced. In the line L3, when the plate voltage was −2.5 V, the difference ΔVth was 0.540 V at the maximum. In the line L4, when the plate voltage was −4 V, the difference ΔVth was 0.382 V at the maximum. As described above, when the impurity concentration of the N-type diffusion layer 11 is increased too much, the threshold voltage difference ΔVth is reduced. Accordingly, it is preferred to set the dose of N-type impurities (N-type impurity concentration) to an appropriate value in the ion implantation process for forming the N-type diffusion layer 11.

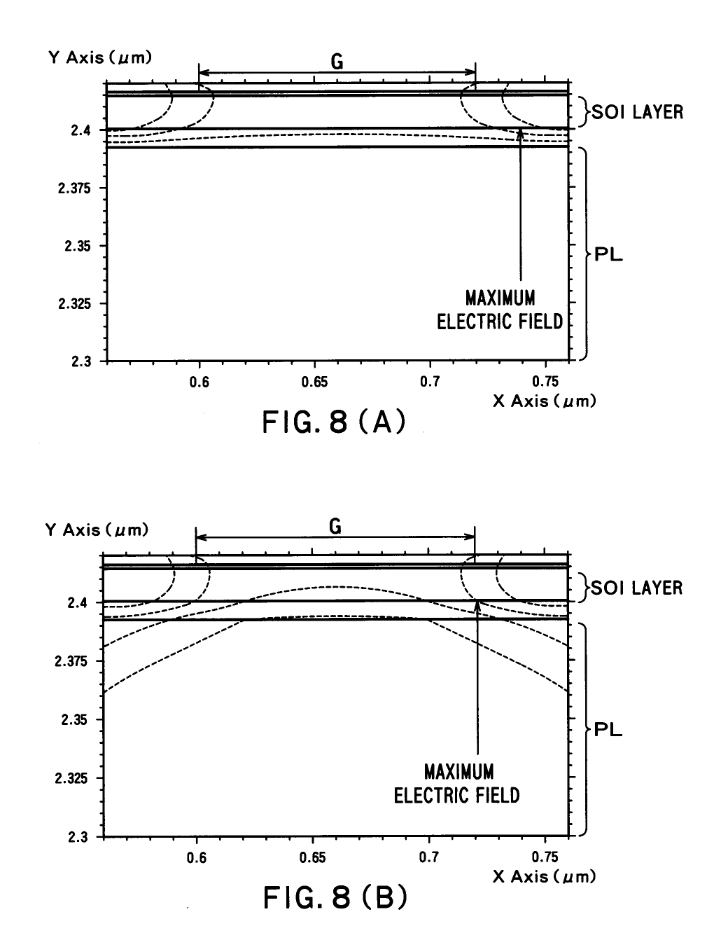

FIG. 8 (A) is a graph showing a potential distribution (equivalent potential contour line) when data “0” is held by the plate voltage −3 V in the conventional FBC memory device. The maximum electric field in the silicon layer 10 was 0.959 MV/cm. The point, at which the electric field is maximized, is located on the bottom of the silicon layer 10. When the value of the electric field is increased, the leak current between the body region B and the source/drain layer is increased and the data retention time is shortened.

FIG. 8 (B) is a graph showing a potential distribution when the data “0” is held by the plate voltage −3 V in the FBC memory device of the first embodiment of the present invention. The maximum electric field in the silicon layer 10 was 0.748 MV/cm. The point, at which the electric field is maximized, is located on the bottom of the silicon layer 10. Since the N-type diffusion layer 11 formed on the surface of the plate PL has a potential higher than the P-type diffusion layer 12, the equivalent potential contour line of the plate PL does not distribute horizontally and distributes two-dimensionally. Accordingly, the electric field of the bottom of the silicon layer 10 in the longitudinal direction thereof is relaxed, and the value of the maximum electric field is also reduced than the conventional FBC memory device.

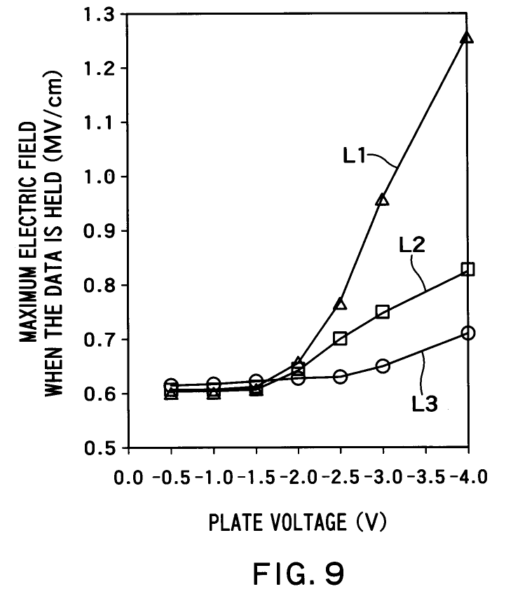

FIG. 9 is a graph showing the maximum electric field in the silicon layer 10 in the memory cell as a function of the plate voltage when the data “0” is held. A line L1 shows the maximum electric field in the silicon layer 10 in the memory cell of the conventional FBC memory device. The maximum electric field is generated on the upper surface of the silicon layer 10 in the range of the plate voltage from 0 V to −1.5 V. When the plate voltage is equal to or less than −2 V, the maximum electric field is generated on the bottom of the silicon layer 10, and the maximum electric field is increased as the plate voltage is reduced.

Lines L2 and L3 show the maximum electric field in the silicon layer 10 in the memory cell of the FBC memory device of the first embodiment. The line L2 is a case in which the dose of N-type impurities of N-type diffusion layer 11 is 2×10¹³ cm⁻². The line L3 is a case in which the dose of N-type impurities is 1.8×10¹⁴ cm⁻². As shown in the lines L2 and L3, in the FBC memory device of the first embodiment of the present invention, when the plate voltage is reduced, an increase of the maximum electric field is slow, so that an FBC memory device having a long data retention time can be obtained.

In the memory cell of the conventional FBC memory device, several methods can be considered to increase the capacitance Csub between the body region B and the plate PL. First, it can be exemplified to use the plate PL of an N-type plate and to place the surface of the plate PL in an accumulated state. Second, it can be exemplified to use the plate PL of a P-type plate and to increase a P-type impurity concentration to reduce the width of a depletion layer. Third, it can be exemplified to reduce the film thickness of the back gate insulation film BGI. However, any of these three methods also increases the capacitance Cdp between the drain layer D and the plate PL. When the capacitance Cdp is increased, a speed is reduced and power consumption is increased when the bit line is driven.

On the other hand, as shown in FIG. 2, the memory cell of the FBC memory device of the first embodiment of the present invention has the N-type diffusion layer 11, which is in an electrically floating state, under the drain layer D. That is, the depletion layer (capacitance Cj) is formed between the N-type diffusion layer 11 and the plate PL, and since the capacitance Cdp between the drain layer D and the plate PL is given by the series connection capacitance of the capacitance Cbg of the back gate insulation film BGI and the capacitance Cj of depletion layer, the capacitance Cdp between the drain layer D and the plate PL can be reduced as compared with the conventional FBC memory device. Accordingly, the speed can be increased and power consumption can be decreased when the bit line is driven.

### Second Embodiment

Subsequently, a second embodiment of the present invention will be explained. The first embodiment of the present invention explains the example in which the P-type diffusion layer 12 is formed in the surface of the plate PL which faces the body region B across the back gate insulation film BGI. On the other hands, in the second embodiment of the present invention, a surface high concentration P-type diffusion layer 14 is formed. Note that explanations of the contents similar to those of the first embodiment are omitted.

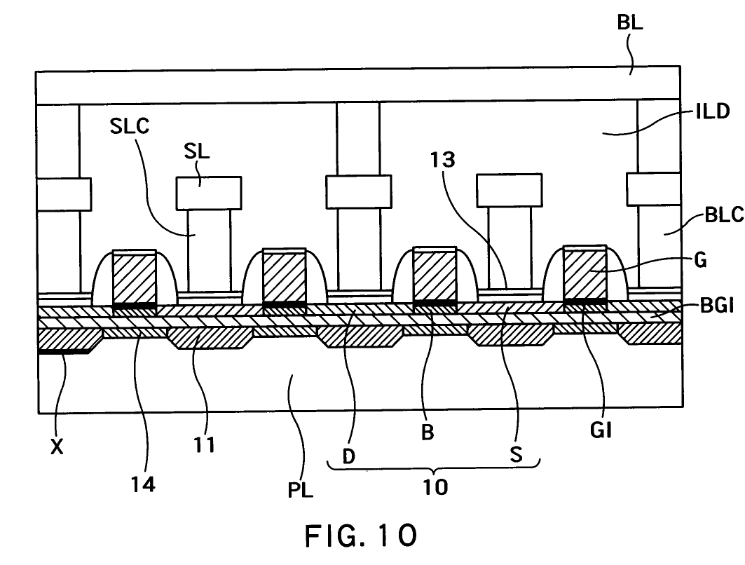

FIG. 10 is a sectional view of a memory cell of an FBC memory device. The second embodiment of the present invention has the surface high concentration P-type diffusion layer 14 in a surface of a plate PL facing a body region B. The P-type impurity concentration in the surface high concentration P-type diffusion layer 14 is 1×10¹⁸ cm⁻³. An N-type diffusion layer 11 is formed in the surface of the plate PL facing a source layer S and a drain layer D across a back gate insulation film BGI. The N-type impurity concentration of the N-type diffusion layer 11 is 2×10¹⁸ cm⁻³.

On the other hand, a large portion of the plate PL has a P-type diffusion layer which has a relatively low concentration with respect to the surface high concentration P-type diffusion layer 14, and a P-type impurity concentration is 1×10¹⁷ cm⁻³ in the vicinity of the surface and increased toward 1×10¹⁸ cm⁻³ as a depth increases. A PN junction X in a longitudinal direction is formed between the N-type diffusion layer 11 and the P-type diffusion layer of the plate PL. The impurity concentration in the vicinity of the PN junction X is 1×10¹⁷ cm⁻³.

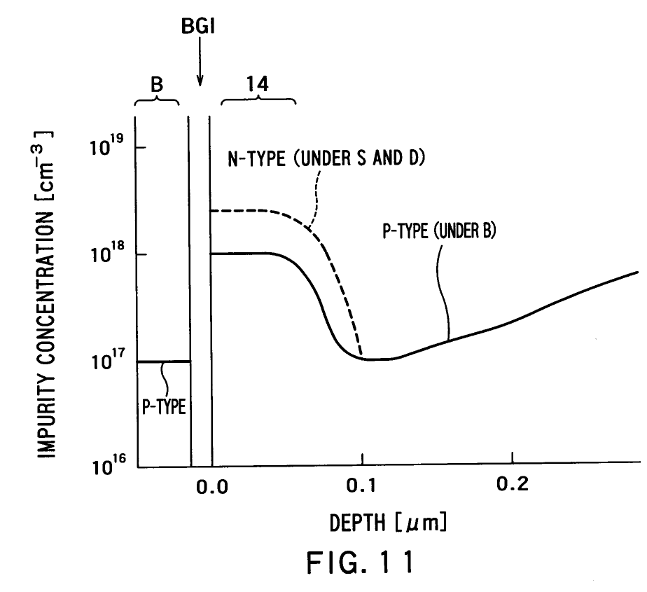

FIG. 11 is a graph showing how the P-type impurity concentration is distributed from the body region B toward the plate PL. The P-type impurity concentration of the body region B is set to a low value (for example, 1×10¹⁷ cm⁻³) to reduce a threshold voltage or to suppress the junction leak current between the body region B and the source/drain layer. On the other hand, the capacitance Csub between the body region B and the plate PL in the structure shown in FIG. 2 is secured by increasing the concentration of the surface high concentration P-type diffusion layer 14. This is because when the concentration of the surface of the plate PL facing the body region B across the back gate insulation film BGI becomes too small, the width of a depletion layer is increased and the capacitance Csub between the body region B and the plate PL is reduced. When the capacitance Csub is reduced, the difference ΔVth of the threshold voltages is reduced when the data of the “0” cell and the “1” cell are read.

The P-type impurity concentration is 1×10¹⁷ cm⁻³ in the vicinity of a portion having a depth of 0.1 μm from the surface of the plate PL. In the region which is deeper than 0.1 μm, there is a P-type diffusion layer, and the P-type impurity concentration is gradually increased in a deeper region. A broken line of FIG. 11 is a graph showing the distribution of the N-type impurity concentration of the N-type diffusion layer 11 formed in the region facing the source layer S and the drain layer D across the back gate insulation film BGI under the source layer S and the drain layer D. Since the P-type impurity concentration is uniformly distributed in the first embodiment of the present invention, the impurity concentration in the vicinity of the junction between the N-type diffusion layer 11 and P-type diffusion layer 12 is 1×10¹⁸ cm⁻³. On the other hand, since the concentration in the vicinity of the PN junction X is low in the second embodiment of the present invention, the capacitance of the PN junction X (the capacitance of the depletion layer) Cj is reduced as compared with the first embodiment of the present invention.

According to the second embodiment of the present invention, the capacitance Cj of the PN junction X can be reduced, and the capacitance Csub between the body region B and the plate PL can be increased as compared with the first embodiment of the present invention. It has two advantages to reduce the capacitance Cj of the PN junction X. First, when the plate voltage is set to a small value, the maximum electric field on the bottom of the silicon layer 10 can be reduced. When a plate voltage is reduced, the potential of the N-type diffusion layer 11 is reduced due to capacitance coupling. However, since the capacitance Cj of the PN junction X of the second embodiment of the present invention is smaller than the first embodiment of the present invention, the potential is suppressed from being reduced, and as a result, the maximum electric field in the silicon layer 10 is more weakened. Second, the bit line BL (drain layer D) can be driven at a high speed or with low power consumption.

Note that it is needless to say that the same advantage as the first embodiment of the present invention, that is, the advantage of suppressing the inversion of the surface of the plate PL by the gated diode structure and the advantage of relaxing the maximum electric field can be obtained also in the second embodiment of the present invention.

### Manufacturing Method of FBC Memory Device of First and Second Embodiments

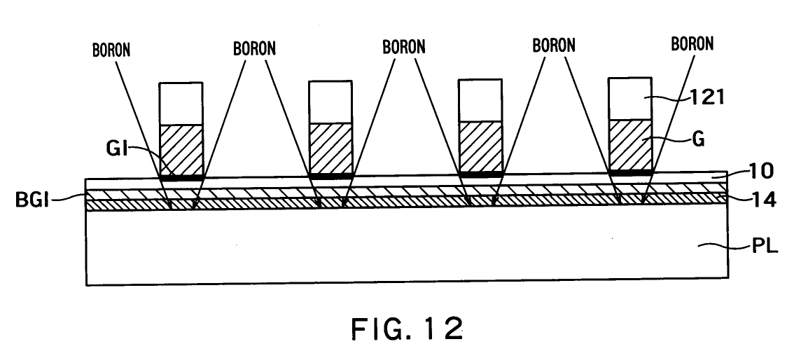

Subsequently, a method of manufacturing the FBC memory device of the first and second embodiments of the present invention will be explained. FIGS. 12 to 15 are sectional views showing the respective processes of the method of manufacturing the FBC memory device of the first and second embodiments of the present invention.

First, an SOI substrate is prepared in which a buried oxide layer (back gate insulation film BGI of FIG. 2) has a thickness of 8 nm and an SOI layer (silicon layer 10) has a thickness of 20 nm. Next, a surface of a bulk silicon substrate is exposed by removing an SOI layer (silicon layer 10) and a buried oxide layer of a logic circuit region. Next, the silicon layer of the portion in which isolation region STI of FIG. 1 will be formed is removed and an oxide is buried to thereby form isolation region STI of FIG. 1.

Next, as shown in FIG. 12, a plate PL including a P-type diffusion layer is formed by implanting boron ion to a memory cell region. For example, boron ion is implanted in an acceleration energy of 230 keV and a dose of 2×10¹² cm⁻², and in an acceleration energy 100 keV and a dose of 1.5×10¹² cm⁻². In the plate PL, a P-type impurity concentration increases with deeper position from a surface thereof.

Although P-type impurities having a lower concentration are introduced to a body region B of a memory cell by the ion implantation process, the P-type impurities may be added when necessary. However, a lower P-type impurity concentration reduces the maximum electric field in the SOI layer, thereby a leak current between the body region B and the source layer S and the drain layer D is reduced. Accordingly, it is preferable that the upper limit of the concentration of the body region B is set to 1×10¹⁷ cm⁻³. Further, the fluctuation of the threshold voltage is reduced by setting the P-type impurity concentration of the body region B to a small value of 1×10¹⁷ cm⁻³. As a result, the number of defective bits (defective memory cells) is reduced. Further, the value of the threshold voltage is reduced by setting the P-type impurity concentration of the body region B to a low value, thereby it is possible to perform writing at a high speed even by a low power supply voltage. Further, P-type impurities and N-type impurities are appropriately introduced to an NMOS transistor and PMOS transistor region constituting the logic circuit.

Next, after a gate insulation film GI having a thickness of 6 nm is formed on an active region of the silicon layer 10, polysilicon having a thickness of 100 nm, which is used as a material of a gate electrode G is deposited. After this process, an SOI layer has a thickness of 15 nm. Next, after a cap SIN 121 having a thickness of 80 nm is deposited, patterning of the gate electrode G (polysilicon) is performed.

Next, the boron concentration of the P-type diffusion layer of the surface of the plate PL under the gate electrode G (polysilicon) is increased up to 1×10¹⁸ cm⁻³ by obliquely implanting boron ion using the gate electrode G (polysilicon) and the cap SIN 121 as a mask, thereby the surface high concentration P-type diffusion layer 14 is formed. At the time, since the body region B is masked with the gate electrode G (polysilicon) and the cap SIN 121, the boron is not implanted thereto, and thus a boron concentration remains 1×10¹⁷ cm⁻³. A structure shown FIG. 12 is formed by the processes described above.

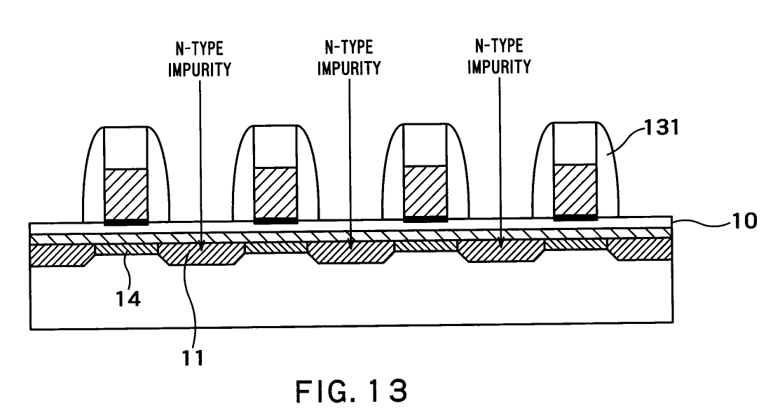

Next, as shown in FIG. 13, spacer SIN 131 are formed to the sidewalls of the gate insulation film GI and the gate electrode G (polysilicon). Then, the N-type diffusion layer 11 is formed by implanting N-type impurities only to the memory cell region using the cap SIN 121 and a spacer SIN 131 as masks. For example, phosphorus ion is implanted in an acceleration energy of 30 keV and a dose of 2×10¹³ cm⁻². The acceleration energy of the phosphorus is set such that it passes through the silicon layer 10 having a thickness of 15 nm and the back gate insulation film BGI having a thickness of 8 nm. Further, the film thickness of the cap SIN 121 and the film thickness of the gate electrode G (polysilicon) are set so that the phosphorus is not introduced t to the body region B. A structure shown in FIG. 13 is formed by the above processes.

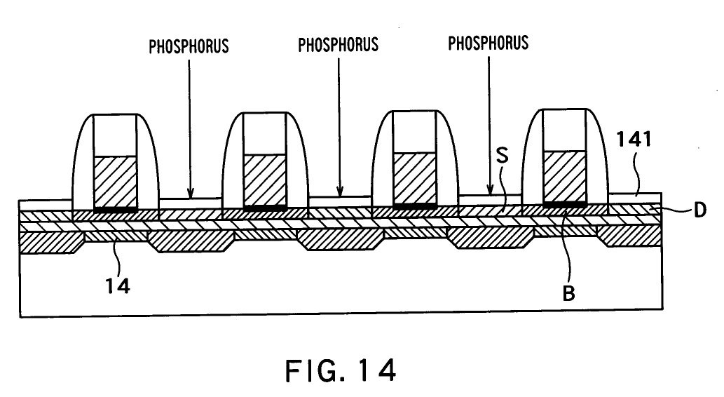

Next, as shown in FIG. 14, an N⁺Si layer 141 is selectively epitaxially grown to reduce a parasitic resistance by increasing the thicknesses of the source layer S and the drain layer D. Next, a high concentration N-type diffusion layer is formed to the source layer S and the drain layer D by implanting phosphorus ion in a dose of 1×10¹⁵ cm⁻² or more. A structure shown in FIG. 14 is formed by the above processes.

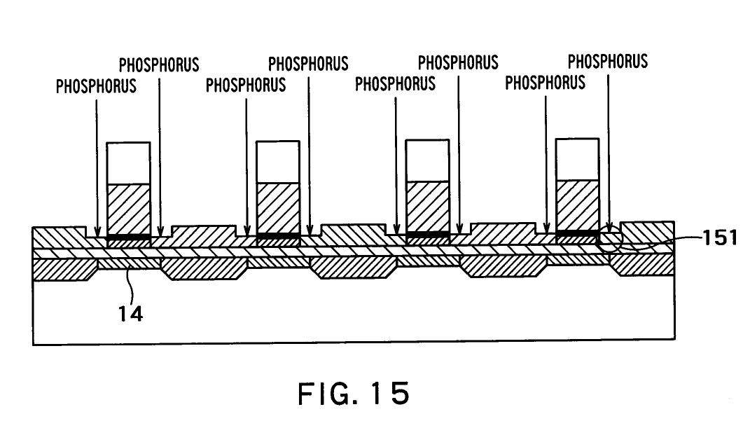

Next, as shown in FIG. 15, after the cap SIN 121 and the spacer SIN 131 are removed, phosphorus ion, for example, is implanted in an acceleration energy of 2.5 keV and a dose of 1×10¹³ cm⁻². As a result, a source-drain-extension layer (the edges of the source layer S and the drain layer D) 151 is formed. A structure shown in FIG. 15 is formed by the above processes.

Thereafter, the structure shown in FIG. 2, that is, the sidewall spacer SIN of the gate electrode G (polysilicon), the silicide layer 13 on the surface of the source layer S, the drain layer D and the gate electrode G (polysilicon), the inter layer dielectric ILD, the source line contact SLC, the bit line contact BLC, the bit line BL and the source line SL are formed using a conventionally known process. The FBC memory device of the second embodiment of the present invention is completed by the above processes. Note that when the process for obliquely implanting boron ion is omitted, the FBC memory device of the first embodiment of the present invention without the surface high concentration diffusion layer 14 is completed.

According to the manufacturing method described above, since the N-type diffusion layer 11 can be formed such that it is self-aligned to the positions where the source layer S and the drain layer D are formed, the fluctuation of the leak current between the body region B and the source/drain layer, the fluctuation of the threshold voltage when data is read out, and the like can be reduced between the memory cells. Since a recent large-scaled and high-density memory device contains a large number of memory cells, it is required to reduce the number of defective bits (defective memory cells). For this purpose, it is important that the fluctuation of the leak current between the memory cells, and the fluctuation of the threshold voltage be small, in addition to that an average leak current is small and the difference between average threshold voltages is large. According to the manufacturing method described above, since the fluctuations of the leak current and the threshold voltage can be reduced, the number of defective bits can be reduced.

Note that when the N-type diffusion layer 11 is formed, N-type impurities may be implanted without forming the spacer SIN 131 to the side surface of the gate electrode G (polysilicon). The spacer SIN 131 may be removed after the ion implantation or may remain as they are. According to the manufacturing method using the spacer SIN 131, the positions of the edges of the source layer S and the drain layer D do not agree with the position of the edge of the N-type diffusion layer 11 on a cross section vertical to the word line WL as shown in FIG. 2. However, since the positions of the edges of both of them can be controlled by the film thickness of the spacer SIN 131, the fluctuations of the leak current between the body region B and the source/drain layer, the threshold voltage when data is read out, and the like can be reduced between the memory cells.

Further, as shown in FIG. 11, using simplified process steps it is possible to realize an impurity concentration distribution in which a thin body region B having a thickness of 20 nm or less has a low P-type impurity concentration, a surface of a plate located 8 nm below the body region B has a P-type impurity concentration one figure larger than that of the body region B, and the plate under the surface has a low P-type impurity concentration (that is, Low-High-Low impurity profile). The maximum electric field in the SOI layer is reduced as described above by reducing the impurity concentration of the body region B, thereby the fluctuation of the threshold voltage can be reduced. Further, the capacitance Csub between the body region B and the plate PL, and the difference between the threshold voltages are increased, because the surface of the plate PL has the high concentration, and the capacitance Cj of the PN junction X is reduced because the plate PL has the low concentration in the deep portion thereof.

### Third Embodiment

Next, a third embodiment of the present invention will be explained. Although the N-type diffusion layer 11 faces the source layer S across the back gate insulation film BGI in the first and second embodiments of the present invention, a source layer S is connected to an N-type diffusion layer 11 through a connector layer C in third embodiment of the present invention. Note that explanation of the same contents as those of the first and second embodiments of the present invention is omitted.

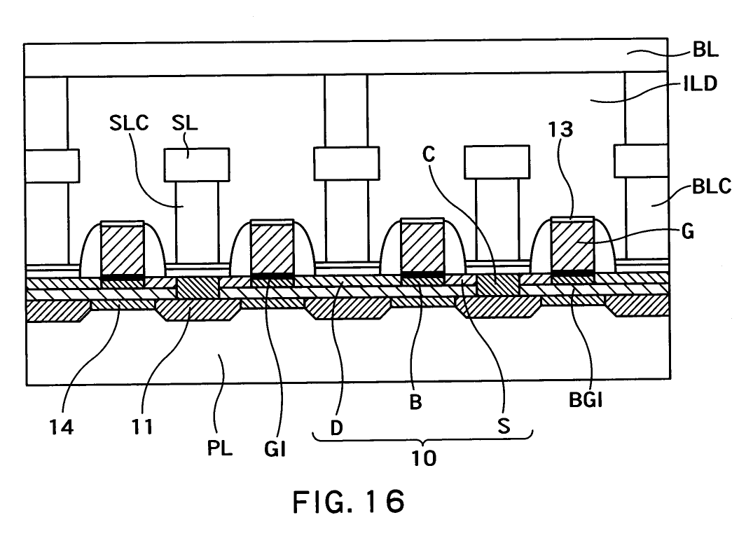

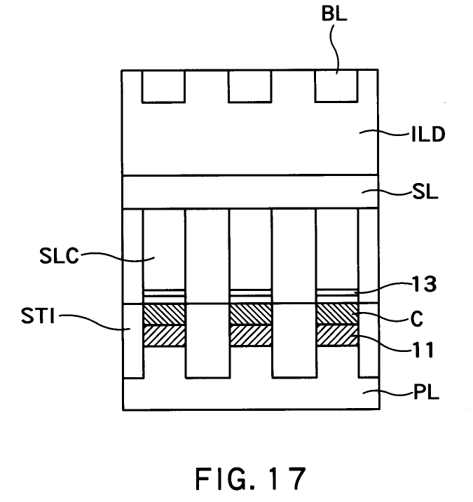

FIG. 16 is a sectional view of an FBC memory device of the third embodiment of the present invention. FIG. 17 is a sectional view of the source layer S of the FBC memory device of the third embodiment of the present invention. The N-type diffusion layer 11 is formed in a surface part of the plate PL which faces a drain layer D and the source layer S. The source layer S is connected to the N-type diffusion layer 11 through the connector layer C to which N-type impurities are introduced. The drain layer D is separated from the N-type diffusion layer 11 by insulation film. A surface high concentration P-type diffusion layer 14 is formed on the surface of the plate PL facing the body region B across the back gate insulation film BGI.

In the third embodiment of the present invention, the difference between threshold voltages is more increased than the conventional FBC memory device as described in the second embodiment of the present invention because the N-type diffusion layer 11 suppresses an increase of the threshold of a “1” cell. Further, since the source layer S is connected to the N-type diffusion layer 11 by the connector layer C, the difference between the threshold voltages is more increased than the FBC memory devices of the first and second embodiments of the present invention. In the structure in which the N-type diffusion layer 11 is connected to the source layer S, the threshold voltage of the “0” cell is more increased than a conventional structure in a region having a low plate voltage. This is because the carrier distribution in the SOI layer is modulated in a region having a low plate voltage with a result that a body potential is reduced when data 0 is written.

Note that although FIG. 16 shows the example in which the source layer S is connected to the N-type diffusion layer 11 through the connector layer C, the same advantage can be obtained in a structure in which the drain layer D is connected to the N-type diffusion layer 11. That is, it is sufficient that at least one of the source layer S and the drain layer D is connected to the N-type diffusion layer 11 through the connector layer C.

The N-type impurity concentration of the connector layer C is about 1×10²⁰ cm⁻³. When the N-type diffusion layer 11 is not formed, the leak current of a PN junction, which is formed by the connector layer C and a surface high concentration P-type diffusion layer 14 of the plate PL, is increased. When the P-type impurity concentration of the plate PL is lowered to suppress the leak current, the capacitance Csub between the body region B and the plate PL is reduced, and thus the difference between threshold voltages is reduced. As shown in FIGS. 16 and 17, the leak current of the PN junction composed of the source layer S and the plate PL can be reduced by forming the N-type diffusion layer 11 having a low N type impurity concentration of 2×10¹⁸ cm⁻³ as a buffer region.

Note that it is needless to say that the maximum electric field is more weakened than a conventional arrangement by the N-type diffusion layer 11 which is formed on the surface of the plate PL facing the source layer S and the drain layer D likewise the first embodiment and the second embodiment of the present invention.

### Fourth Embodiment

Subsequently, a fourth embodiment of the present invention will be explained. Although the plate PL is formed by introducing P-type impurities in the first to third embodiments of the present invention, the fourth embodiment of the present invention uses P-type polysilicon as material of a plate PL. Note that explanation of the same contents as those of the first to third embodiments of the present invention is omitted.

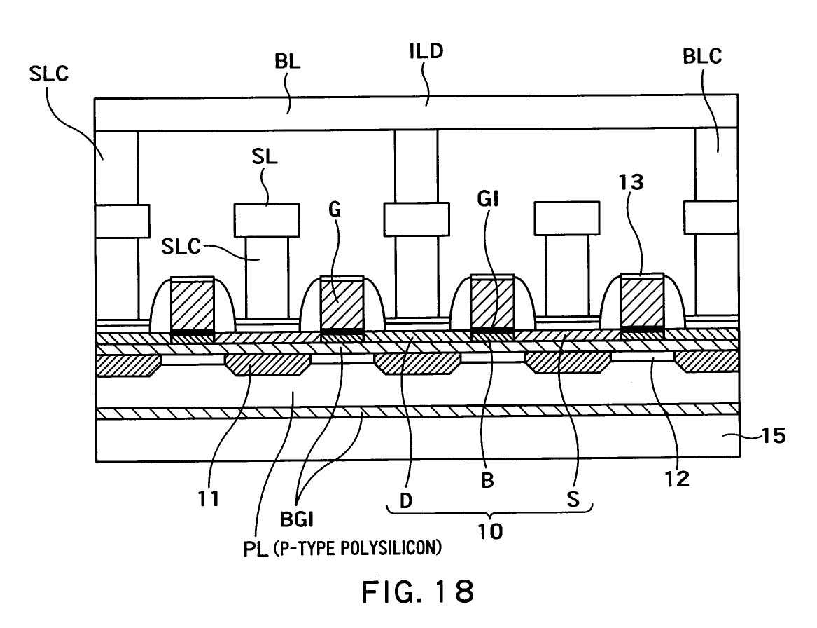

FIG. 18 is a sectional view of an FBC memory device of the fourth embodiment of the present invention. The fourth embodiment of the present invention uses the P-type polysilicon as the material of the plate PL material as shown in FIG. 18. The P-type polysilicon contains P-type impurities of 1×10¹⁸ cm⁻³. The back gate insulation film BGI is formed under a plate PL (P-type polysilicon).

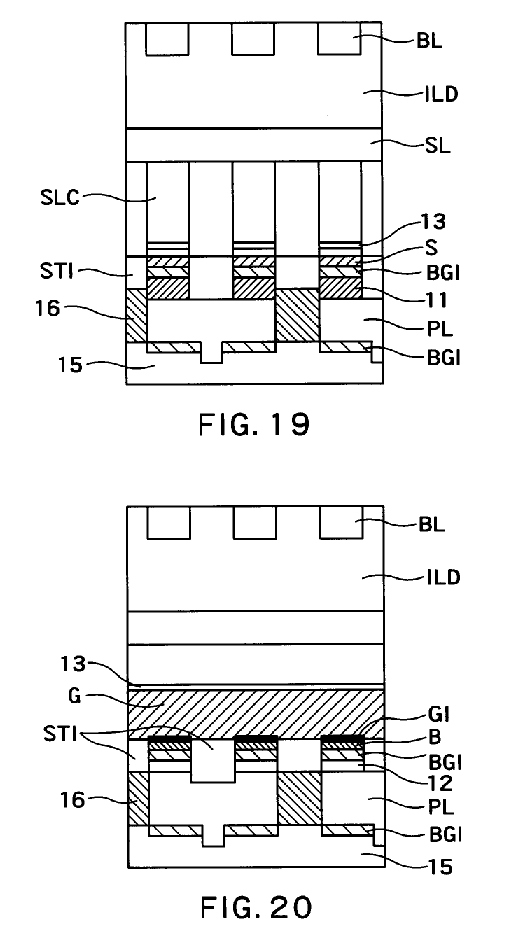

FIG. 19 is a sectional view of the source layer S of the FBC memory device of the fourth embodiment of the present invention. FIG. 20 is a sectional view of a gate electrode G and a body region B of the FBC memory device of the fourth embodiment of the present invention. The plate PL (P-type polysilicon) is connected to a P well 15 as shown in FIGS. 19 and 20. A voltage is applied to the P-well 15 by a contact (not shown). A BOX film 16 is formed between the P-well 15 and isolation region STI.

A transistor is formed on an SOI substrate having a 150 nm-thick buried oxide layer in a logic circuit region. Since the parasitic capacitance between the source layer S and the drain layer D and the plate PL can be reduced, a circuit is operated at a high speed as well as in low power consumption. The number of defective bits can be reduced by forming a back gate insulation film BGI having a thickness of 10 nm or less and by increasing the capacitance Csub between the body region B and the plate PL in the memory cell region as shown in FIG. 18. That is, an optimum structure is formed to operate the circuit at the high speed as well as in the low power consumption and to reduce the number of the defective bit.

### Manufacturing Method of FBC Memory Device of Fourth Embodiment

Next, a method of manufacturing of the FBC memory device of the fourth embodiment of the present invention will be explained.

First, an SOI substrate having the buried oxide layer (BOX film 16) having a thickness of 150 nm and an SOI layer having a thickness of about 20 nm is prepared. Next, the isolation region STI of FIGS. 19 and 20 is formed by removing a silicon layer in the portion, in which the isolation region STI will be formed, and burying an oxide likewise the first embodiment of the present invention.

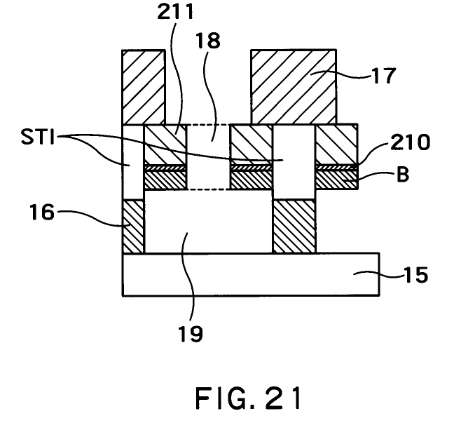

FIG. 21 is a sectional view showing the method of manufacturing the FBC memory device of the fourth embodiment of the present invention. An oxide 210, a SIN mask 211 and a resist 17 are formed on the body region B of the memory cell region. A resist 17 is formed to cover every other isolation region formed in a line shape in the memory cell region, and oxides and the BOX films 16 of the isolation region STI are removed by anisotropic etching in the opening of the resists. Next, a void 19 is formed by removing the BOX film 16 under the body region B by ammonium fluoride etching. A structure shown in FIG. 21 is formed by the above processes.

Next, the back gate insulation film BGI having a thickness of 8 nm is formed under the body region B by thermal oxidation. At the time, the back gate insulation film BGI is also formed on the side surface of the body region B and the surface of the P-well 15.

Next, after P-type polysilicon is deposited, an anisotropic etch-back processing is performed so that the P-type polysilicon remains under the body region B and is removed in the opening 18.

Next, as shown in FIG. 20, after the back gate insulation film BGI of the opening 18 is removed, P-type polysilicon is deposited, and etching back is performed so that the P-type polysilicon also remains in the opening 18. The P-type polysilicon under the body region B is connected to the P-well 15 through the P-type polysilicon of the opening 18. Thereafter, the opening 18 is filled with the oxide to form the Isolation region STI.

A P-type impurity concentration is set to 1×10¹⁷ cm⁻³ in a process for implanting boron ion into the body region B. Note that a process, which forms the surface high concentration P-type diffusion layer 14 under the body region B by obliquely implanting P-type impurities using a gate electrode G as a mask, is not necessary different from the second embodiment of the present invention.

The manufacturing method described above includes steps of preparing the SOI substrate having the thick buried oxide layer (BOX film 16), partially removing the oxide of the isolation region STI after the isolation region STI is formed, removing the BOX film 16 under the body region B, and replacing the BOX film 16 with the back gate insulation film BGI and the plate PL (P-type polysilicon). However, a substrate having a SiGe layer in place of the BOX film 16 may be prepared, the oxide of the isolation region STI may be partially removed after the isolation region STI is formed, the SiGe layer under the body region B may be selectively removed by wet etching, and the SiGe layer may be replaced with the back gate insulation film BGI and the plate PL (P-type polysilicon).

In the manufacturing method of the FBC memory device of the fourth embodiment of the present invention, the P-type impurity concentration of the body region B and the plate PL, which face with each other across the thin back gate insulation film BGI having a thickness of 10 nm or less can be easily changed by 1 figure or more. In a conventional doping method performed by the ion implantation of boron, when it is intended to increase the concentration of the surface of the plate PL, since the ion implantation is also performed to the body region B, it is difficult to independently set a concentration. In other words, it is difficult to increase the capacitance between the body region B and the plate PL by increasing the surface of the plate PL concentration while reducing a leak current by reducing the concentration of the body region B.

According to the manufacturing method of the FBC memory device of the fourth embodiment of the present invention, it is possible to make a reduction of the leak current compatible with an increase of the difference between threshold voltages because the concentration of the plate can be set to 1×10¹⁸ cm⁻³ or more while setting the concentration of the body region to about 1×10¹⁷ cm⁻³.

Further, the film thickness and the material of the back gate insulation film BGI can be optionally set. For example, the back gate insulation film BGI may be an ONO film (three-layered structure of oxide-nitride-oxide). It is possible to suppress the leak current between the body region B and the plate PL and to increase the capacitance therebetween by employing the ONO film.

Further, the threshold voltage may be adjusted by trapping charges (electrons or holes) in the nitride of the ONO film of the memory cell. As described above, the threshold voltage has a fluctuation. Thereby, the number of defective bits can be reduced by lowering the fluctuation of the threshold voltage by adjusting the threshold voltage of a memory cell whose threshold voltage is greatly deviated from an average value.

### Fifth Embodiment

Subsequently, a fifth embodiment of the present invention will be explained. In the fifth embodiment of the present invention, an example using a so-called multi-fin-type transistor memory cell will be explained. Note that explanation of the same contents as those of the first to fourth embodiments of the present invention are omitted.

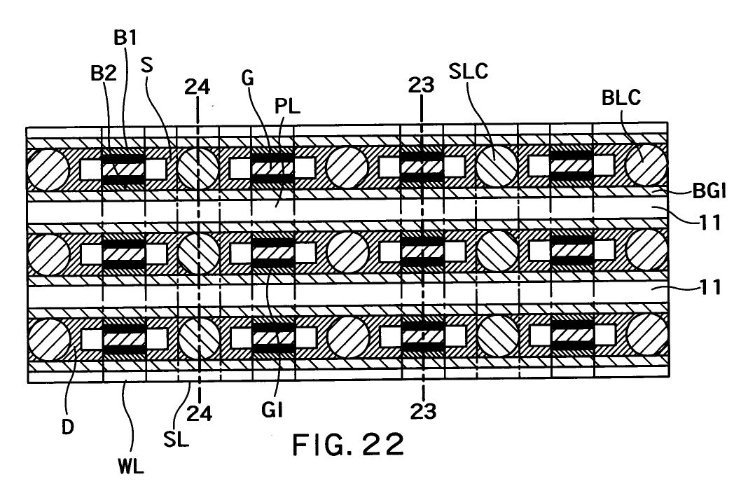

FIG. 22 is a plan view of a FBC memory of the fifth embodiment of the present invention. As shown in FIG. 22, a body region B is formed so as to be sandwiched between a source layer S and a drain layer D. The body region B has two body portions B1 and B2 provided in a word line WL direction. Both the body portions B1 and B2 are connected to the same source layer S and the same drain layer D.

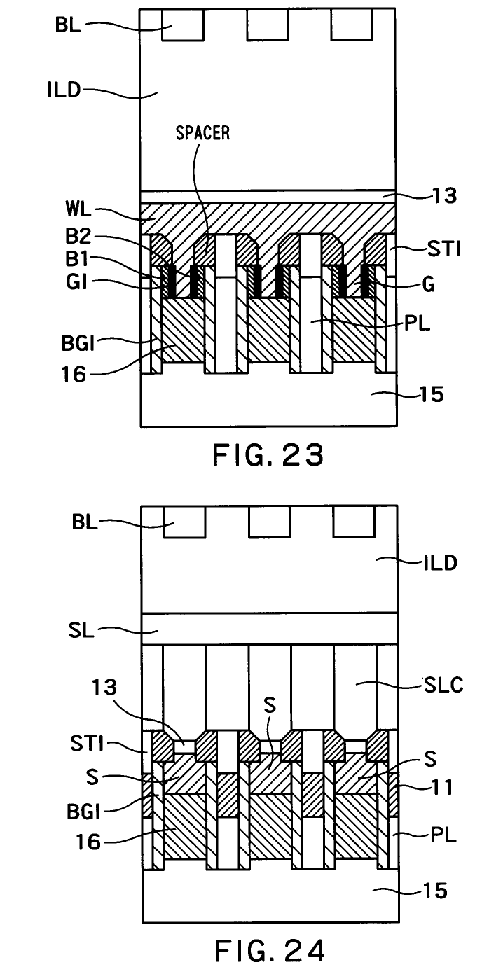

FIG. 23 is a sectional view of a gate electrode G and the body region B along a line 23-23 of FIG. 22. As shown in FIG. 23, gate insulation films GI are formed to the side surface (second surface) of the body portions B1 and B2, and a gate electrode G is formed so as to be in contact with the gate insulation films GI. Further, back gate insulation film BGI is formed to the side surface (first surface) of the body portions B1 and B2 opposite to the second surface thereof to which the gate insulation film GI is formed, and a plate PL is formed so as to be in contact with the back gate insulation film BGI. Further, a P-well 15 is formed under the plate PL, the back gate insulation films BGI and a BOX layer 16.

As shown in FIG. 23, the cross sections of the body portion B1, the gate insulation film GI, the gate electrode G, the gate insulation films GI and the body portion B2 appear in this order along the word line WL. A channel width is equal to the height of the body portions B1 and B2.

FIG. 24 is a sectional view showing the portion of a source layer S along a line 24-24 of FIG. 22. As shown in FIG. 24, the back gate insulation film BGI is formed to both the side surfaces of the source layer S and the BOX film 16, and the plate PL, an N-type diffusion layer 11 and isolation region STI are formed so as to be in contact with the back gate insulation film BGI. Further, a P-well 15 is formed under the plate PL, the back gate insulation film BGI and BOX layer 16.

In the fifth embodiment of the present invention, since a so-called multi-fin-type memory cell (in which a channel is formed on a side surface of the body region B and to which a plurality of fin type transistors are connected to flow a current in a horizontal direction) is used as one memory cell, a channel width is twice the height of the body region B. Since the multi-fin-type transistor memory cell is used, the channel width can be increased even if the size of the memory cell is reduced, thereby a drain current difference ΔIcell can be increased when the data of a “0” cell and a “1” cell are read out.

### Manufacturing Method of FBC Memory Device of Fifth Embodiment

Next, a method of manufacturing an FBC memory device of the fifth embodiment of the present invention will be explained. Note that explanation of the same contents as those of the manufacturing methods of the first to fourth embodiments of the present invention are omitted.

First, an SOI substrate having an about 150 nm thick buried oxide layer and an about 70 nm thick SOI layer is prepared. Next, a portion of a silicon layer 10 where the isolation region STI of FIGS. 23 and 24 is formed is removed and an oxide is buried to thereby form the isolation region STI likewise the first embodiment of the present invention. Next, the oxide and the BOX film 16 of the isolation region STI are removed.

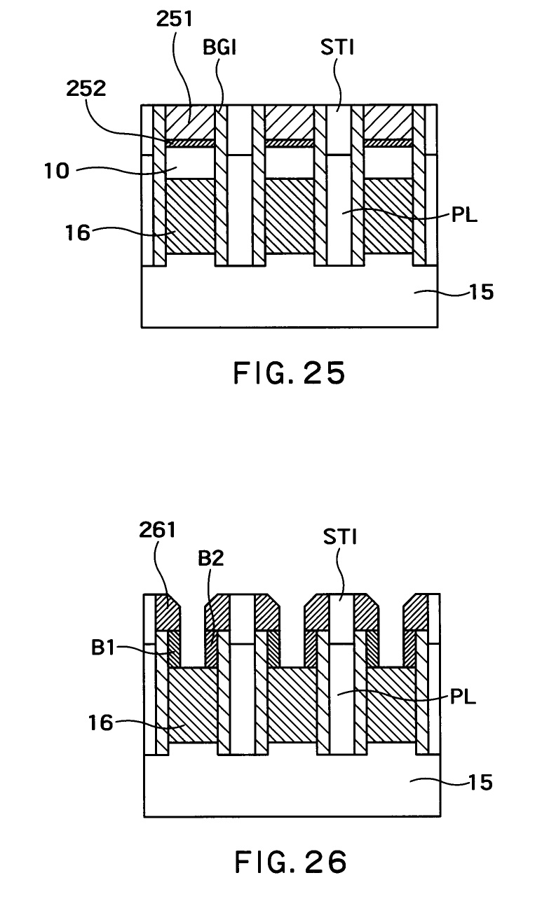

FIGS. 25 and 26 are sectional views showing the respective processes of the method of manufacturing the FBC memory device of the fifth embodiment of the present invention. As shown in FIG. 25, the back gate insulation film BGI is formed to the side surfaces of the silicon layer 10 by depositing an insulation film and performing an isotropic etching. Next, P-type polysilicon is deposited and an oxide with which the upper portion of the isolation region STI is filled is formed after etching back is performed. A structure shown in FIG. 25 is formed by the above processes. In stead of using P-type polysilicon, a non-doped polysilicon may be deposited and etched back. Then, P-type impurities may be implanted selectively into the non-doped polysilicon. As a result, a plate PL with P-type impurity of about 1×10¹⁸ cm⁻³ is formed while keeping the silicon layer 10 undoped.

Next, after a SIN mask 251 is removed, P-type impurities of about 1×10¹⁷ cm⁻³ are introduced into the silicon layer 10.

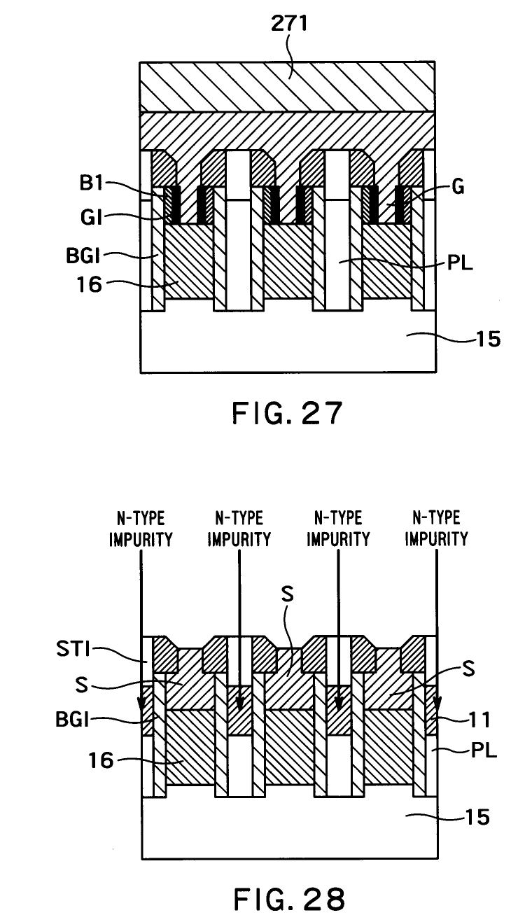

Next, as shown in FIG. 26, a spacer SIN 261 is formed on the silicon layer 10. The spacer SIN 261 is formed on the side surface of the isolation region STI. Then, the silicon layer 10 in the vicinity of a region where the gate electrode G of FIG. 27 will be formed is removed by an isotropic etching using the spacer SIN 261 as a mask. A structure shown in by FIG. 26 is formed by the above processes.

The thickness of the fin is adjusted by the film thickness of the spacer SIN 261. Note that the etching is not performed in the source layer S and drain layer D (not shown). Thereafter, the gate electrodes GI are formed to the side surfaces of the body portions B1 and B2, and polysilicon acting as the gate electrodes GI is deposited. The gate electrode G is formed by the same method as the first embodiment of the present invention.

FIGS. 27 and 28 are sectional views when the N-type diffusion layer 11 is formed. As shown in FIG. 28, the N-type diffusion layer 11 is formed in the region facing the source layer S across the back gate insulation film BGI by implanting N-type impurities. On the other hand, as shown in FIG. 27, since the gate electrodes G and the cap SIN 271 are formed on the body region B, the N-type impurities are not ion implanted into the body region B. A structure shown in FIGS. 27 and 28 is formed by the above processes.

According to the manufacturing method of the FBC memory device of the fifth embodiment of the present invention, the N-type diffusion layer 11 can be formed to the positions of the source layer S and the drain layer D by a self-alignment manner likewise the first embodiment of the present invention.

What is claimed is:

1. A semiconductor memory device, comprising:
a first semiconductor layer and a second semiconductor layer facing each other across a back gate insulation film;
a first conductive type plate provided in the first semiconductor layer;
a gate insulation film provided on a surface of the second semiconductor layer so as to be in contact with a second surface opposite to a first surface in contact with the back gate insulation film;
a gate electrode provided so as to be in contact with the gate insulation film;
a first conductive type body region provided in the region facing the gate electrode across the gate insulation film in the second semiconductor layer;
a second conductive type source layer and a second conductive type drain layer provided to sandwich the body region in the second semiconductor layer; and
a second conductive type diffusion layer provided in a surface region of the first semiconductor layer facing the source layer and the drain layer across the back gate insulation film,
wherein the body region is in an electrically floating state and stores data by accumulating or discharging charges.

2. A semiconductor memory device according to claim 1, further comprising a high concentration diffusion layer of first conductive type provided in a surface region of the first semiconductor layer, the high concentration diffusion layer facing the body region across the back gate insulation film and having a higher concentration than that in the plate.

3. A semiconductor memory device according to claim 2, wherein the body region contains impurities having a concentration lower than the high concentration diffusion layer.

4. A semiconductor memory device according to claim 1, wherein the second conductive type diffusion layer is in an electrically floating state.

5. A semiconductor memory device according to claim 4, further comprising a high concentration diffusion layer of first conductive type provided in a surface region of the first semiconductor layer, the high concentration diffusion layer facing the body region across the back gate insulation film and having a higher concentration than the plate.

6. A semiconductor memory device according to claim 5, wherein the body region contains impurities having a concentration lower than the high concentration diffusion layer.

7. A semiconductor memory device according to claim 1, further comprising a second conductive type connector layer for connecting at least one of the source layer and the drain layer to the second conductive type diffusion layer.

8. A semiconductor memory device according to claim 7, further comprising a high concentration diffusion layer of first conductive type provided in a surface region of the first semiconductor layer, the high concentration layer facing the body region across the back gate insulation film and having a higher concentration than the plate.

9. A semiconductor memory device according to claim 8, wherein the body region contains impurities having a concentration lower than the high concentration diffusion layer.

10. A semiconductor memory device according to claim 1, wherein the first surface and the second surface are located on a side surface of the second semiconductor layer.

11. A method of manufacturing a semiconductor memory device for storing data by accumulating or discharging charges in a body region in an electrically floating state, comprising:
forming a structure which has a first semiconductor layer, a second semiconductor layer, a gate insulation film, and a gate electrode, the first semiconductor layer including a first conductive type plate and facing the second semiconductor layer across a back gate insulation film, the second semiconductor layer including a first conductive type body region;
forming a second conductive type diffusion layer in the plate by introducing second conductive type impurities into the first semiconductor layer using the gate electrode as a mask; and
forming a source layer and a drain layer by introducing second conductive type impurities into the second semiconductor layer using the gate electrode as a mask.

12. A method of manufacturing a semiconductor memory device according to claim 11, further comprising:
forming a high concentration diffusion layer of first conductive type having a higher concentration than the plate in a region facing the body region by introducing first conductive type impurities into the first semiconductor layer using the gate electrode as a mask.

13. A method of manufacturing a semiconductor memory device according to claim 11, wherein the forming the structure comprises:
forming a void by removing a buried oxide layer under the body region in an SOI substrate;
forming the back gate insulation film in the void; and
filling the void with the first semiconductor layer.

14. A method of manufacturing a semiconductor memory device according to claim 11, wherein the forming the structure comprises:
removing a silicon layer of isolation region in an SOI substrate;
forming the back gate insulation film on a side surface of the body portion of the SOI substrate; and
filling the isolation region with the first semiconductor layer.

15. A method of manufacturing a semiconductor memory device according to claim 11, wherein the forming the structure comprises:
forming the first conductive type plate in the first semiconductor layer by introducing the first conductive type impurities into the first semiconductor layer;
forming the first conductive type body region in the second semiconductor layer;
forming the gate insulation film on a surface of the second semiconductor layer so as to be in contact with a second surface opposite to a first surface in contact with the back gate insulation film; and
forming the gate electrode so as to be in contact with the gate insulation film by performing patterning after a gate electrode material is deposited.
